(19) United States
(12) Patent Application Publication
(10) Pub. No.: US 2014/0315381 A1
(43) Pub. Date: Oct. 23, 2014

(54) INTERCONNECT FABRICATION AT AN INTEGRATED SEMICONDUCTOR PROCESSING STATION

(71) Applicant: Applied Materials, Inc., Santa Clara, CA (US)

(72) Inventors: You Wang, San Jose, CA (US); Wen-chiang Tu, Fremont, CA (US); Zhihong Wang, Sunnyvale, CA (US)

(21) Appl. No.: 13/866,449

(22) Filed: Apr. 19, 2013

(51) Int. Cl. H01L 21/768; H01L 21/67

(52) U.S. Cl. CPC H01L 21/768; H01L 21/67092; H01L 21/76819
USPC 438/618; 204/242; 204/198

(57) ABSTRACT

A stand-alone processing station of a semiconductor manufacturing system may be configured to fabricate interconnects on a semiconductor wafer. The stand-alone processing station may include a chemical mechanical polishing (CMP) module and an electro-chemical deposition (ECD) module. The CMP module may be configured to receive a semiconductor wafer from another processing station and selectively remove a first top layer from the received semiconductor wafer. The ECD module may be configured to receive a semiconductor wafer from the CMP module and fill interconnect features with metal. The CMP module may also be configured to receive a semiconductor wafer from the ECD module and selectively remove excess metal and a second top layer from the semiconductor wafer. Methods of forming an interconnect on a semiconductor wafer are also provided, as are other aspects.

### FIELD

The invention relates generally to semiconductor device manufacturing, and more particularly to interconnect fabrication.

### BACKGROUND

An integrated circuit (IC) is a semiconductor device that may be fabricated on a semiconductor wafer. A semiconductor wafer may be a thin slice of semiconductor material, such as silicon crystal. An IC typically includes circuit elements, such as, e.g., transistors, and intricate structures known as “interconnects.” Interconnects are electrical conductors, usually made of copper, that electrically connect the circuit elements to each other and to external connections. An IC may have many interconnect layers separated by insulator layers that together form complex, multilevel networks. Interconnects may include horizontal wiring and vertical pathways, which may be contacts and/or vias. Contacts may connect horizontal wires on a first interconnect layer to circuit elements below, and vias may connect horizontal wires on one interconnect layer to horizontal wires on an adjacent interconnect layer.

Fabricating interconnects on semiconductor wafers may involve sequentially repeating one or more chemical mechanical polishing (CMP) processes at one interconnect processing station and one or more electro-chemical deposition (ECD) processes at another interconnect processing station. A CMP process may remove topographic features and/or one or more top layers from a partially-processed semiconductor wafer to produce a flat surface for subsequent processing. An ECD process may be used to deposit a metal on a top layer of a semiconductor wafer to construct one or more interconnects. Interconnect fabrication may be one of the more process-intensive and cost-sensitive aspects of IC manufacturing. Accordingly, a need exists to provide more efficient and less-costly methods and apparatus for forming interconnects.

### SUMMARY

According to one aspect, an interconnect fabrication station is provided. The interconnect fabrication station comprises a chemical mechanical polishing (CMP) module, an electro-chemical deposition (ECD) module, and a controller electrically coupled to the CMP module and to the ECD module. The controller is configured to cause the CMP module to remove a first top layer from a semiconductor wafer, cause the ECD module to deposit a metal on the semiconductor wafer, and cause the CMP module to remove excess deposited metal and a second top layer from the semiconductor wafer.

According to another aspect, a method of forming an interconnect is provided. The method comprises receiving a semiconductor wafer at an interconnect fabrication station configured to form one or more interconnects on a semiconductor wafer, applying to the semiconductor wafer at the interconnect fabrication station a first selective chemical mechanical polishing process, applying to the semiconductor wafer at the interconnect fabrication station a selective electro-chemical deposition process, and applying to the semiconductor wafer at the interconnect fabrication station a second selective chemical mechanical polishing process.

According to a further aspect, another method of forming an interconnect is provided. The method comprises providing a chemical mechanical polishing (CMP) module in a stand-alone processing station; providing an electro-chemical deposition (ECD) module in the stand-alone processing station; providing an input/output port in the stand-alone processing station configured to receive and return a semiconductor wafer to and from a wafer transport system of a semiconductor manufacturing system, the wafer transport system external to the stand-alone processing station; providing at least one wafer handler in the stand-alone processing station configured to transfer a wafer within the stand-alone processing station between the CMP module and the ECD module and between the input/output port and the CMP module; and providing a controller in the stand-alone processing station configured to control processing of a semiconductor wafer in the CMP module and the ECD module and to control transfer of the semiconductor wafer within the stand-alone processing station.

Still other aspects, features, and advantages of the invention may be readily apparent from the following detailed description wherein a number of example embodiments and implementations are described and illustrated, including the best mode contemplated for carrying out the invention. The invention may also include other and different embodiments, and its several details may be modified in various respects, all without departing from the scope of the invention. Accordingly, the drawings and descriptions are to be regarded as illustrative in nature, and not as restrictive. The drawings are not necessarily drawn to scale. The invention covers all modifications, equivalents, and alternatives falling within the scope of the invention.

### BRIEF DESCRIPTION OF DRAWINGS

The skilled artisan will understand that the drawings, described below, are for illustration purposes only. The drawings are not intended to limit the scope of this disclosure in any way.

FIG. 1 illustrates a simplified block diagram of several processing stations of a semiconductor manufacturing system according to the prior art.

FIGS. 2A-2D illustrate sequential cross-sectional views of a semiconductor wafer having an interconnect formed thereon according to the prior art.

FIG. 3 illustrates a simplified block diagram of a stand-alone interconnect fabrication station according to embodiments.

FIG. 4 illustrates a flowchart of a method of forming an interconnect according to embodiments.

FIGS. 5A-5D illustrate sequential cross-sectional views of a semiconductor wafer having an interconnect formed thereon according to embodiments.

FIG. 6 illustrates a flowchart of another method of forming an interconnect according to embodiments.

### DETAILED DESCRIPTION

Reference will now be made in detail to the example embodiments of this disclosure, which are illustrated in the accompanying drawings. Wherever possible, the same reference numbers will be used throughout the drawings to refer to the same or like parts.

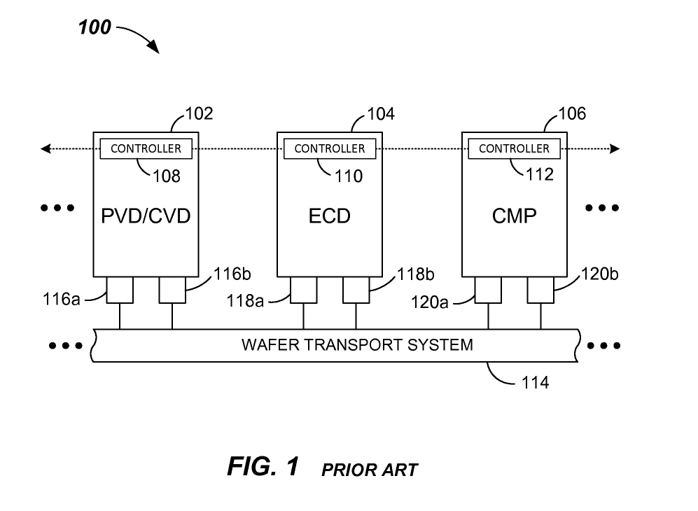

In one aspect, an interconnect fabrication station may be configured to form interconnects on a semiconductor wafer. The interconnect fabrication station, which may be a stand-alone processing station, may be coupled to receive and return semiconductor wafers to and from other processing stations of a semiconductor manufacturing system. The interconnect fabrication station may include a chemical mechanical polishing (CMP) module and an electro-chemical deposition (ECD) module. The CMP module may be configured to selectively remove a first top layer from a semiconductor wafer received from another processing station and selectively remove excess metal and, in some embodiments, a second top layer from a semiconductor wafer processed and received from the ECD module. The ECD module may be configured to deposit a metal on the semiconductor wafer processed and received from the CMP module. The interconnect fabrication station may have higher wafer throughput (e.g., the number of wafers processed per hour) than conventional multi-station interconnect fabrication processes. In other aspects, methods of forming interconnects are provided, as will be explained in greater detail below in connection with FIGS. 1-6.

FIG. 1 shows a portion of a known semiconductor manufacturing system 100 having a plurality of wafer processing stations. Semiconductor manufacturing system 100 may include a PVD/CVD (physical vapor deposition/chemical vapor deposition) station 102, an ECD station 104, and a CMP station 106. PVD/CVD station 102 may have a controller 108, ECD station 104 may have a controller 110, and CMP station 106 may have a controller 112. Controllers 108, 110, and 112 may each be any suitable general-purpose computer, microprocessor, microcontroller, or the like, and each may include a central processing unit (CPU), a memory, an input/output interface, and other suitable circuit components. Controllers 108, 110, and 112 may be configured to automatically control the processing, robotic operations, timings, and the like associated with the process(es) performed at their respective stations. In some embodiments, the controllers may be coupled to each other and/or to a master controller (not shown) that may be configured to automatically control an entire semiconductor manufacturing process, or a portion thereof, in which semiconductor wafers are processed through PVD/CVD station 102, ECD station 104, and CMP station 106. In some systems, one or more of controllers 108, 110, and 112 may operate independently of each other.

Semiconductor manufacturing system 100 may also include a wafer transport system 114 configured to transport one or more wafers or wafer carriers from one of the wafer processing stations of semiconductor manufacturing system 100 to one or more other wafer processing stations of semiconductor manufacturing system 100. Wafer transport system 114 may be any suitable type of wafer transport system, including, e.g., an overhead and/or conveyor-type system. Wafer transport system 114 may be coupled to first and second input/output ports 116a and 116b of PVD/CVD station 102, first and second input/output ports 118a and 118b of ECD station 104, and first and second input/output ports 120a and 120b of CMP station 106. Each of input/output ports 116a, 116b, 118a, 118b, 120a, and 120b may be configured to receive and/or return one or more wafers or wafer carriers to and from wafer transport system 114. At some stations, one input/output port (e.g., 116a, 118a, and/or 120a) may be used for receiving wafers, while the other input/output port (e.g., 116b, 118b, and/or 120b) may be used for returning wafers. At other stations, each input/output port may be used as needed. In some systems, stations 102, 104, and 106 may each have more or less than two input/output ports.

PVD/CVD station 102 may provide one or more physical vapor deposition and/or one or more chemical vapor deposition processes for depositing one or more materials on a semiconductor wafer to form, e.g., an insulator layer, a barrier layer, a barrier seed layer, and/or any other suitable layer. PVD/CVD station 102 may be a multi-chamber station that may include one or more processing, heating, cooling, degassing, transfer, buffer, and pass-through chambers. The processing chambers may include one or more deposition and/or etching chambers, wherein one or more of the etching chambers may create, e.g., interconnect features (e.g., trenches, contacts, and/or vias) in an insulation layer. PVD/CVD station 102 may also include suitable robotics/wafer handlers to transfer wafers within PVD/CVD station 102 and to and from input/output ports 116a and 116b. PVD/CVD station 102 may alternatively or additionally include other suitable components and/or capabilities. PVD/CVD station 102 may be, e.g., an Endura® Amber™ PVD system and/or a Producer® BLOk™ PECVD system, both by Applied Materials, of Santa Clara, Calif.

ECD station 104 may provide an electro-chemical deposition process in which metal ions are removed from an electrolyte solution and deposited on a charged surface. This process may also be referred to as electrochemical plating, electroplating, or electrodeposition. ECD station 104 may include one or more electrolyte cells, wherein each electrolyte cell may include an electrolyte solution, an opening for receiving a semiconductor wafer, a wafer holder for holding the semiconductor in the electrolyte solution, an anode (i.e., a positive electrode) positioned in the electrolyte solution, and one or more electrical contact elements (i.e., cathodes) for electrically contacting a surface of a semiconductor wafer upon which a metal is to be electro-chemically deposited. A voltage/current may be established through the electrolyte solution between the anode and the semiconductor wafer surface. Controller 110 may control the electrical power supplied to the anode. The resulting positive metal ions in the electrolyte solution may be attracted to and deposited on the negatively charged semiconductor wafer surface. ECD station 104 may also include a thermal anneal chamber, a spin-rinse-dry (SRD) unit, an electrolyte solution replenishing system, and suitable robotics/wafer handlers to transfer wafers within ECD station 104 and to and from input/output ports 118a and 118b. Metals that may be deposited by ECD station 104 may include copper, gold, silver, chromium, rhodium, nickel, zinc, and the like. ECD station 104 may alternatively or additionally include other suitable components and/or capabilities. ECD station 104 may be, e.g., a Raider® GT ECD system, by Applied Materials, of Santa Clara, Calif.

CMP station 106 may provide one or more chemical mechanical polishing (CMP) processes, which may also be referred to as chemical mechanical planarization. CMP processes may use one or more rotating polishing pads pressed against a surface of a wafer. The polishing pads may include grooves and micropores, and may be used with a polishing liquid, a slurry, or a chemically active slurry applied to the pads. A slurry may be a liquid with a suspension of abrasive solids. CMP station 106 may have multiple CMP units. Each CMP unit may perform the same or a different CMP process, such as, e.g., bulk metal layer removal, metal clearing polishing, barrier layer removal, buffing, etc. For example, a first CMP unit may perform an initial CMP process that removes most of a bulk metal layer from a wafer, a second CMP unit may perform an intermediate CMP process that removes the remaining bulk metal layer and over polishes the resulting top surface of the wafer, and a third unit may perform a final CMP process that removes a barrier layer and buffs the resulting top surface of the wafer. CMP station 106 may also include one or more cleaning units that may scrub and rinse a wafer with selected chemicals and/or water to remove residual particles or organics left on the processed surface of the wafer after CMP processing. The residual particles or films may cause defects that may cause the wafer to become inoperable. Each CMP unit may include a rotating platen that may hold a polishing pad, a platen drive motor, a fluid delivery device that may deliver a slurry, polishing liquid, or rinsing liquid to a polishing pad on the rotating platen, two or more liquid supply tubes that supply the slurry or polishing liquid, a carrier head that may hold a wafer against the polishing pad, and a pad conditioning device that may recondition the polishing surface of the polishing pad. CMP station 106 may further include a wafer transfer location and robotics/wafer handlers to transfer wafers within CMP station 106 and to and from input/output ports 120a and 120b. CMP station 106 may alternatively or additionally include other suitable components and/or capabilities. CMP station 106 may be, e.g., a Reflexion® GT™ CMP System, by Applied Materials, of Santa Clara, Calif.

Semiconductor manufacturing system 100 may have one or more other processing stations (not shown), which may be part of an FEOL (front end of the line) fabrication process that may include, e.g., wafer doping and transistor fabrication, that may precede stations 102, 104, and/or 106 in a process flow. Semiconductor manufacturing system 100 may also have one or more other processing stations (not shown), which may be part of a BEOL (back end of the line) fabrication process that may include, e.g., dicing and packaging, that may follow stations 102, 104, and/or 106 in a process flow.

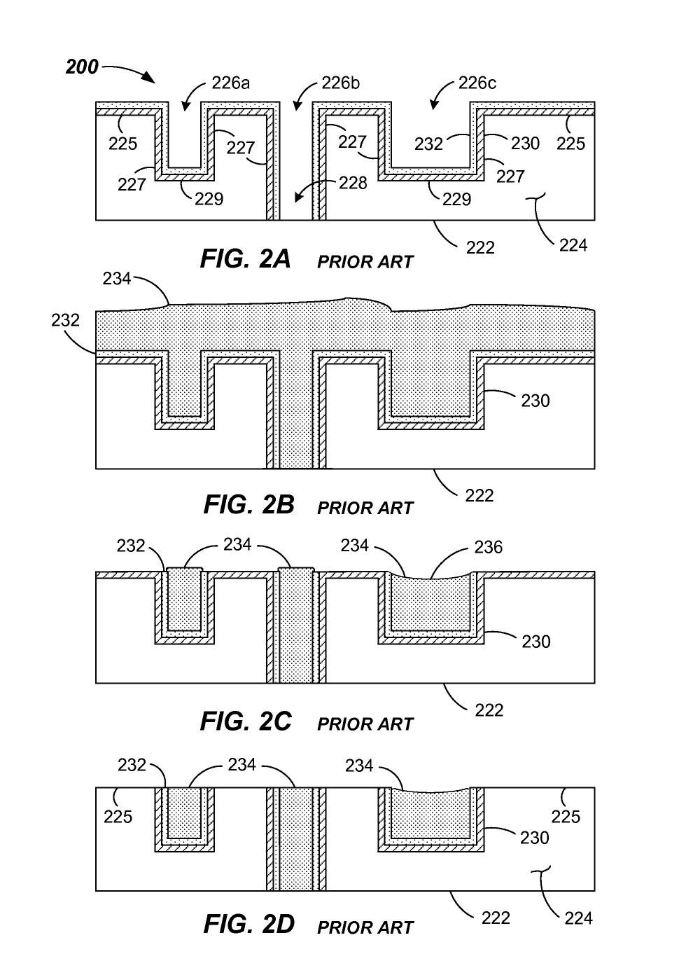

FIGS. 2A-2D illustrate a known interconnect fabrication process 200 that may be performed by semiconductor manufacturing system 100 in accordance with the prior art. FIG. 2A shows a top portion of a partially-processed semiconductor wafer 222 that may be received by ECD station 104 at one of input/output ports 118a or 118b via wafer transport system 114. Wafer 222 may be received from, e.g., PVD/CVD station 102 or another wafer processing station of semiconductor manufacturing system 100. Wafer 222 may have circuit elements (not shown), such as transistors, and an insulator layer 224 formed thereon. In some known processes, Insulator layer 224 may be on the order of 1000 to 5000 Ångströms thick and may be formed with a dielectric material, such as, e.g., silicon dioxide, at PVD/CVD station 102 or another suitable wafer processing station (not shown) coupled to wafer transport system 114. Insulator layer 224 may have interconnect features 226a, 2226b, and/or 226c formed therein. Interconnect features 226a, 226b, and 226c may be trenches etched in insulator layer 224 to be used for horizontal wiring. Interconnect feature 226b may also include a contact or via 228 etched completely through insulator layer 224 to be used for vertically connecting to a circuit element or horizontal wire on an adjacent lower layer (not shown). Interconnect features 226a, 226b, and 226c may be etched in insulator layer 224 at PVD/CVD station 102 or another suitable wafer processing station of semiconductor manufacturing system 100.

Semiconductor wafer 222 may further include a barrier layer 230 and a barrier seed layer 232. Barrier layer 230 may be deposited over a top surface 225 of insulator layer 224 and on sidewalls 227 and bottoms 229 of interconnect features 226a, 226b, and 226c. Barrier layer 230 may be formed with tantalum/tantalum nitride, ruthenium/tantalum nitride, titanium/titanium nitride, or cobalt/tantalum nitride and may prevent, e.g., copper atoms from a subsequently-deposited copper metal layer from diffusing or migrating into insulator layer 224, which may cause short circuits. Barrier seed layer 232 may be deposited over barrier layer 230 and is typically formed from the same metal, e.g., copper, as a subsequently electro-chemically deposited metal, such that the deposited seed layer becomes contiguous with the deposited metal. Barrier layer 230 and/or barrier seed layer 232 may each be typically 10 to 100 Ångströms thick and may be deposited on wafer 222 by a physical or a chemical vapor deposition process performed at PVD/CVD station 102 or another suitable wafer processing station of semiconductor manufacturing system 100. In some known processes, other suitable layers of material(s) may be deposited on semiconductor wafer 222 between insulator layer 224 and barrier layer 230 and/or between barrier layer 230 and barrier seed layer 232.

FIG. 2B shows semiconductor wafer 222 after processing at ECD station 104. Wafer 222 may undergo a bulk metal deposition process at ECD station 104 wherein a bulk metal layer 234 is deposited on semiconductor wafer 222 over barrier seed layer 232, filling interconnect features 226a, 226b, and 226c. Bulk metal layer 234 may be copper and may be on the order of 2000 to 5000 Ångströms thick. The bulk metal deposition process may take about 60 minutes to perform in some known processes. Afterwards, wafer 222 may be returned to wafer transport system 114 via one of input/output ports 118a or 118b for transport to CMP station 106.

FIG. 2C shows semiconductor wafer 224 after undergoing a first chemical mechanical polishing process at a first CMP unit of CMP station 106. The first polishing process may remove most of bulk metal layer 234 above barrier layer 230 from wafer 222, and may take about 10 minutes to perform in some known processes. In some cases where copper is used as the bulk metal, a phenomenon known as “dishing” may occur. Dishing 236 may occur as result of a polishing pad bending slightly during the first polishing process. This can cause some bulk metal 234 to be removed from an interconnect feature below barrier layer 230, which may resemble a side profile of a dish. Dishing may adversely affect the electrical properties of the resulting horizontal wire. After the first polishing process, wafer 222 may be cleaned at a cleaning unit in CMP station 106 as described above, and may be transferred to another CMP unit of CMP station 106.

FIG. 2D shows semiconductor wafer 222 after undergoing a second chemical mechanical polishing process at, in some known processes, a second CMP unit of CMP station 106. The second polishing process may remove the remaining bulk metal layer 234 and barrier layer 230 above top surface 225 of insulator layer 224. After the second polishing process, wafer 222 may be cleaned at a cleaning unit in CMP station 106 as described above, completing this layer of interconnect fabrication. Note that in some known processes, wafer 222 may undergo alternative or additional CMP processing than that described herein. Wafer 222, as shown in FIG. 2D, may be ready for additional processing. For example, wafer 222 may be transported to PVD/CVD station 102 to have an additional insulator layer deposited thereon and additional interconnect features etched therein. Thereafter, wafer 222 may be returned to ECD station 104 and CMP station 106 to have another interconnect layer fabricated thereon. Wafer 222 may alternatively be transported to another processing station of semiconductor manufacturing system 100 for (additional) BEOL processing.

Wafer throughput related to interconnect fabrication may be adversely affected by wafer processing time at ECD station 104 and/or CMP station 106, wafer transport times to and from ECD station 104 and/or CMP station 106, and wafer queuing times at ECD station 104 and/or CMP station 106 (i.e., the time a wafer waits to be received at a processing station). For example, a batch of wafers processed at ECD station 104 may have to wait before CMP station 106 can receive those wafers because CMP station 106 may be processing another batch of wafers received from another processing station. Similarly, the amount of time required to transfer wafers between an input/output port and wafer transport system 114, and the amount of time required to transport wafers from one processing station to another via wafer transport system 114, which may depend on the amount of wafer traffic already on wafer transport system 114 and the proximity of ECD station 104 and CMP station 106 to each other, may adversely affect wafer throughput.

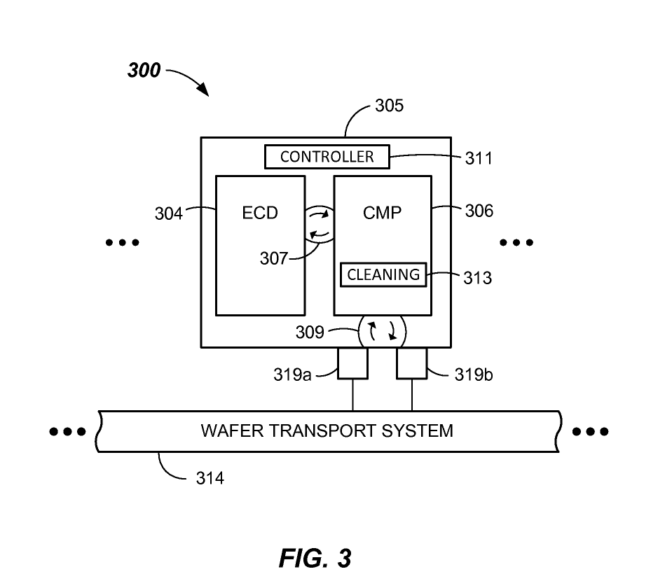

FIG. 3 shows a portion of a semiconductor manufacturing system 300 having an interconnect fabrication station 305 in accordance with one or more embodiments. Semiconductor manufacturing system 300 may have one or more other processing stations (not shown), which may be part of an FEOL (front end of the line) process, that may precede interconnect fabrication station 305 in a process flow, and one or more other processing stations (not shown), which may be part of a BEOL (back end of the line) process, that may follow interconnect fabrication station 305 in a process flow. Semiconductor manufacturing system 300 may include a wafer transport system 314 configured to transport one or more wafers or wafer carriers between interconnect fabrication station 305 and one or more processing stations of semiconductor manufacturing system 300. Wafer transport system 314 may be any suitable type of wafer transport system, including, e.g., an overhead and/or conveyor-type system.

Interconnect fabrication station 305 may include an ECD module 304, a CMP module 306, a wafer handler 307, a wafer handler 309, a controller 311, and input/output ports 319a and 319b. Input/output ports 319a and 319b may be configured to receive and return semiconductor wafers to and from wafer transport system 314. In some embodiments, one of input/output ports 319a and 319b may be used for receiving wafers from wafer transport system 314, while the other may be used for returning wafers to wafer transport system 314. In other embodiments, each input/output port 319a and 319b may be used as needed. In some embodiments, interconnect fabrication station 305 may have more or less than two input/output ports. For example, in some embodiments, one input/output port may be configured to receive and hold one or more wafer carriers.

Wafer handlers 307 and 309 may be configured to transfer wafers within interconnect fabrication station 305. Wafer handler 307 may be coupled to ECD module 304 and to CMP module 306, and may be configured to transfer semiconductor wafers between ECD module 304 and CMP module 306 and, in some embodiments, within ECD module 304 and/or CMP module 306. Wafer handler 309 may be coupled to input/output ports 319a and 319b and to CMP module 306, and may be configured to transfer a semiconductor wafer between input/output ports 319a and 319b and CMP module 306. In some embodiments, wafer handler 307 and wafer handler 309 may each be part of a same station wafer handling system within interconnect fabrication station 305. In some embodiments, semiconductor wafers may be transferable directly between ECD module 304 and input/output ports 319a and/or 319b either by wafer handler 309 a third wafer handler (not shown), or the station wafer handling system. Wafer handlers 307 and 309 may be, or may be part of, any suitable robotic/wafer handling system(s).

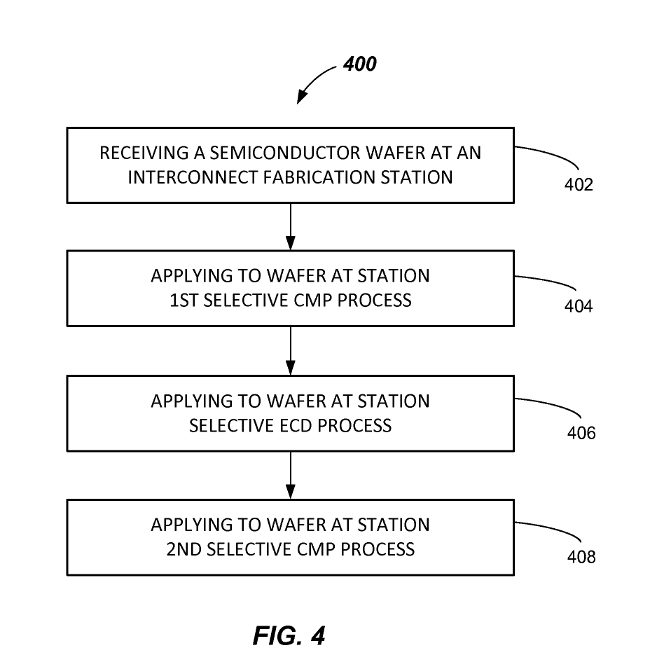

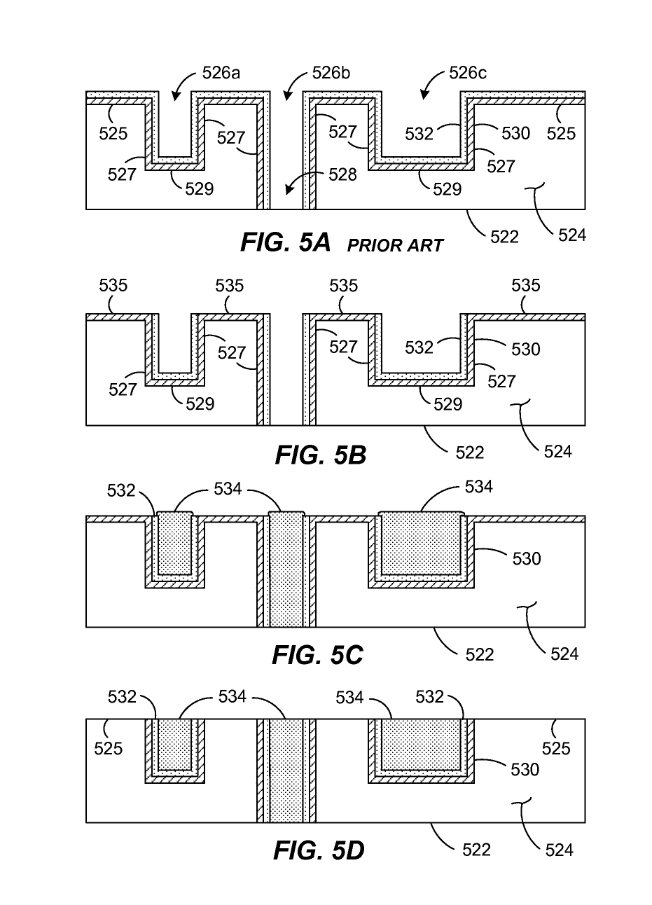

Controller 311 may be coupled to ECD module 304, CMP module 306, wafer handler 307, wafer handler 309, and input/output ports 319a and 319b. Controller 311 may be any suitable general-purpose computer, microprocessor, microcontroller, or the like, and may include a central processing unit (CPU), a memory, an input/output interface, and other suitable circuit components. Controller 311 may be configured to independently and automatically control the processing, robotic/wafer transfer operations, timings, and the like associated with the processes performed at interconnect fabrication station 305. For example, controller 311 may be configured to automatically control the processes performed by ECD module 304 and CMP module 306, as described further below in connection with FIGS. 4 and 5. Controller 311 may also be configured to cause a semiconductor wafer to be transferred from CMP module 306 to ECD module 304 and from ECD module 304 to CMP module 306. Controller 311 may further be configured to cause a semiconductor wafer to be transferred from input/output port 319a or 319b to CMP module 306 and from CMP module 306 to input/output port 319a or 319b. In some embodiments, controller 311 may be coupled to other controllers of other processing stations and/or to a master controller (not shown) that may be configured to automatically control an entire semiconductor manufacturing process, or a portion thereof, in which semiconductor wafers are processed through interconnect fabrication station 305. Controller 311 may include alternative or additional suitable components and/or capabilities.

ECD module 304 may be configured to deposit a metal, such as, e.g., copper, on a semiconductor wafer and more particularly, in some embodiments, to fill interconnect features on the semiconductor wafer with deposited metal and leave most of a top surface of the semiconductor wafer without deposited metal. ECD module 304 may include one or more electrolyte cells, which may be similar or identical to the electrolyte cells of ECD station 104. Controller 311 may control the electrical power supplied to the one or more electrolyte cells. In some embodiments, ECD module 304 may include a segmented anode that may distribute plating current uniformly across a wafer surface. ECD module 304 may also include a thief ring that may limit or prevent high plating current at a wafer's edge. In some embodiments, ECD module 304 may further include a thermal anneal chamber, a spin-rinse-dry (SRD) unit, and an electrolyte solution replenishing system, which may be similar or identical to those of ECD station 104. ECD module 304 may, in some embodiments, perform some or all of the processes of ECD station 104. ECD module 304 may alternatively or additionally include other suitable components and/or capabilities.

CMP module 306 may be configured to remove topographic features and/or one or more top layers from a partially-processed semiconductor wafer to produce a flat surface for subsequent processing. CMP module 306 may include at least two CMP units. A first CMP unit may be configured to remove a first top layer from a semiconductor wafer. In some embodiments, the first top layer may be a barrier seed layer. A second CMP unit may be configured to remove excess deposited metal and a second top layer from a semiconductor wafer. In some embodiments, the deposited metal may be copper and the second top layer may be a barrier layer. CMP module 306 may, in some embodiments, have more or less than two CMP units. Each CMP unit may be similar or identical to CMP units described above in connection with CMP station 106. For example, each CMP unit may include a rotating platen that may hold a polishing pad, a platen drive motor, a fluid delivery device that may deliver a slurry, polishing liquid, or rinsing liquid to a polishing pad on the rotating platen, two or more liquid supply tubes that supply the slurry or polishing liquid, a carrier head that may hold a wafer against the polishing pad, and a pad conditioning device that may recondition the polishing surface of the polishing pad. CMP module 306 may also include a cleaning unit 313. Cleaning unit 313 may be configured to scrub and/or rinse a wafer with selected chemicals and/or water to remove residual particles or films left on a processed surface of the wafer after CMP processing. CMP module 306 may alternatively or additionally include other suitable components and/or capabilities.

Alternatively or additionally to processing semiconductor wafers, interconnect fabrication station 305 may, in some embodiments, be configured to fabricate interconnects on other types of substrates and/or workpieces.

FIGS. 4 and 5A-5D illustrate a method 400 of forming an interconnect in a semiconductor wafer. Method 400 may include at process block 402 receiving a semiconductor wafer at an interconnect fabrication station configured to form one or more interconnects on a semiconductor wafer. Method 400 may be performed at interconnect fabrication station 305 (of FIG. 3), wherein a wafer may be received at input/output port 319a or 319b via wafer transport system 314. The received wafer may be, e.g., a wafer 522 as shown in FIG. 5A, which may be similar or identical to wafer 222 of FIG. 2A.

FIG. 5A shows a top portion of partially-processed semiconductor wafer 522 that may have circuit elements (not shown), such as transistors, and an insulator layer 524 formed thereon. In some embodiments, insulator layer 524 may be on the order of 8000 Ångströms thick and may be formed with a dielectric material, such as, e.g., silicon dioxide (SiO₂) or silicon nitride (Si₃N₄) at a suitable PVD and/or CVD station, such as, e.g., PVD/CVD station 102, coupled to wafer transport system 314. Insulator layer 524 may have interconnect features 526a, 5226b, and/or 526c formed therein. Interconnect features 526a, 526b, and 526c may be trenches or grooves etched in insulator layer 524 to be used for horizontal wiring. Interconnect feature 526b may also include a contact or via 528 etched completely through insulator layer 524 to be used for vertically connecting to a circuit element or horizontal wire on an adjacent lower layer (not shown). Interconnect features 526a, 526b, and 526c may be etched out of insulator layer 524 at, e.g., PVD/CVD station 102 or another suitable wafer processing station of semiconductor manufacturing system 300.

Semiconductor wafer 522 may further include a barrier layer 530 and a barrier seed layer 532. Barrier layer 530 may be deposited over a top surface 525 of insulator layer 524 and on sidewalls 527 and bottoms 529 of interconnect features 526a, 526b, and 526c. Barrier layer 530 may be formed with tantalum, tantalum nitride, titanium nitride, tungsten, or tungsten nitride and may prevent copper atoms from a subsequently-deposited copper metal layer from diffusing or migrating into insulator layer 524, which may cause short circuits. Barrier seed layer 532 may be deposited over barrier layer 530 and is typically formed from the same metal, e.g., copper, as a subsequently electro-chemically deposited metal, such that the deposited seed layer becomes contiguous with the deposited metal. In some embodiments, barrier layer 530 and/or barrier seed layer 532 may each be on the order of 200-300 Ångströms thick and may be deposited on wafer 522 by a physical or a chemical vapor deposition process performed at, e.g., PVD/CVD station 102 or another suitable wafer processing station of semiconductor manufacturing system 300. In some embodiments, other suitable layers of material(s) may be deposited on semiconductor wafer 522 between insulator layer 524 and barrier layer 530, between barrier layer 530 and barrier seed layer 532, and/or on top of barrier seed layer 532.

At process block 404, method 400 may include applying to a semiconductor wafer at the interconnect fabrication station a first selective chemical mechanical polishing (CMP) process. In some embodiments, the first selective CMP process may include removing a first layer, which may be a barrier seed layer, from a top surface of the semiconductor wafer. For example, a semiconductor wafer received at interconnect fabrication station 305 may be transferred by wafer handler 309 from input/output port 319a or 319b to a first CMP unit of CMP module 306 for processing. Controller 311 may cause CMP module 306 to remove a first top layer from the semiconductor wafer. In some embodiments, the first selective CMP process may include a slurry having a high selectivity of copper to barrier materials. In some embodiments, an abrasive free slurry may be used which may include phosphate acid, ammonium hydrogen citric, glycine, BTA and oxidizer in the following composition:

| | (NH4)2H | | | |
|---|---|---|---|---|
| H3PO4 | Citric | Glycine | BTA | Oxidizer |
| 1-5 | 0.2-2 wt % | 0.1-2 | 0.1-0.5 | 0.2-1 |
| vol % | | wt % | wt % | vol % |

In some embodiments, controller 311 may cause the semiconductor wafer to be cleaned at cleaning unit 313 of CMP module 306 after processing at the first CMP unit. The processed wafer may be, e.g., wafer 522 of FIG. 5B, which shows wafer 522 after having barrier seed layer 532 removed from a top surface 535 of barrier layer 530 by a first selective CMP process. Barrier seed layer 532 may remain over barrier layer 530 on sidewalls 527 and bottoms 529 of interconnect features 526a, 526b, and 526c.

Method 400 may include at process block 406 applying to a semiconductor wafer at the interconnect fabrication station a selective electro-chemical deposition process. In some embodiments, the selective electro-chemical deposition process may include depositing a metal in the interconnect features wherein no deposited metal remains on most of a top surface of the semiconductor wafer. In some embodiments, the metal may be copper. For example, after wafer 522 is processed at the first CMP unit in CMP module 306, wafer 522 may be transferred by wafer handler 307 to ECD module 304, where wafer 522 may undergo a metal deposition process. Controller 311 may cause ECD module 304 to deposit a metal on the semiconductor wafer. As shown in FIG. 5C, a layer of metal 534 may be deposited on semiconductor wafer 522 over barrier seed layer 532 such that interconnect features 526a, 526b, and 526c may be over-filled with metal 534 (i.e., filled to a level above barrier layer 530). In some embodiments, a small amount of metal 534 may be deposited on surface 535 of barrier layer 530 around the periphery of interconnect features 526a, 526b, and 526c. At least partly because barrier seed layer 532, which may act as a wetting and nucleation layer (which may promote the growth of a subsequently deposited layer) is removed from top surface 535 of barrier layer 530 prior to the metal deposition process at ECD module 304, no metal 534 is deposited on most of top surface 535, as shown in FIG. 5C. Accordingly, no bulk metal deposition as shown in FIG. 2B may occur in method 400. In some embodiments, the metal deposition process at ECD module 304 may take less than about one minute to perform. Afterwards, wafer 522 may be transferred by wafer handler 307 from ECD module 304 back to CMP module 306.

At process block 408, a second selective chemical mechanical polishing (CMP) process may be applied to a semiconductor wafer at the interconnect fabrication station. In some embodiments, the second selective CMP process may include removing excess deposited metal and a second layer, which may be a barrier layer, from a top surface of the wafer. For example, a wafer received from ECD module 304 may be transferred to a second CMP unit of CMP module 306. Controller 311 may cause CMP module 306 to remove excess deposited metal and a second top layer from the semiconductor wafer. As shown in FIG. 5D, the second selective CMP process, which may be performed at the second CMP unit, may remove excess metal 534 and barrier layer 530 from top surface 525 of insulator layer 524. Because no bulk metal deposition occurred at process block 406, method 400 may not include bulk metal removal as shown in FIG. 2C, and as a result, dishing 236 may not occur. In some embodiments, the second selective CMP process may take less than about 30 seconds to perform. After processing, wafer 522 may in some embodiments be cleaned at cleaning unit 313 of CMP module 306, thus completing one layer of interconnect fabrication. In some embodiments, wafer 522 may undergo alternative or additional CMP processing than the first and/or second selective CMP processes described herein to produce wafer 522 of FIG. 5D. Wafer 522 of FIG. 5D, may be ready for additional processing. For example, wafer 522 may be transported via wafer transport system 314 to a suitable PVD/CVD station to have an additional insulator layer deposited thereon and additional interconnect features etched therein. Thereafter, wafer 522 may be returned to interconnect fabrication station 305 to have another interconnect layer fabricated thereon. Upon completion of all interconnect fabrication, wafer 522 may be transported to another processing station of semiconductor manufacturing system 300 for (additional) BEOL processing.

Wafer throughput related to interconnect fabrication in semiconductor manufacturing systems having interconnect fabrication station 305 may be improved in comparison to that of systems having separate ECD and CMP stations, such as, e.g., system 100 having ECD station 104 and CMP station 106. In particular, wafer transport times in, e.g., wafer transfer system 114, wafer queuing times at, e.g., ECD station 104 and/or CMP station 106, and wafer transfer times between, e.g., wafer transport system 114 and the input/output ports of ECD station 104 and CMP station 106, may be eliminated and/or substantially reduced in a semiconductor manufacturing system having interconnect fabrication station 305, thus contributing to improved wafer throughput. In some embodiments, one or more CMP and ECD processes may require less processing time than those in, e.g., ECD station 104 and/or CMP station 106, further improving wafer throughput in systems having interconnect fabrication station 305.

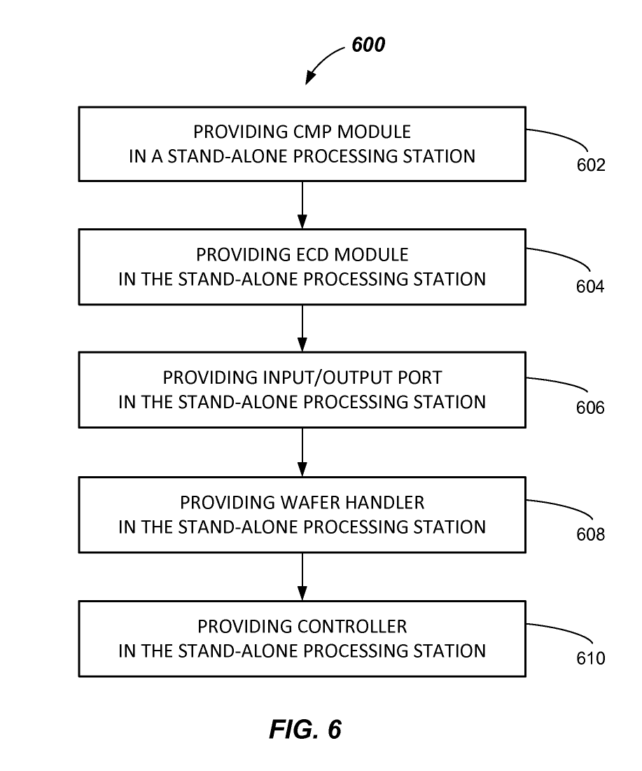

FIG. 6 illustrates a second method 600 of forming an interconnect in accordance with one or more embodiments. At process block 602, method 600 may include providing a CMP module in a stand-alone processing station. In some embodiments, the stand-alone processing station may be similar or identical to, e.g., interconnect fabrication station 305, and the CMP module may be similar or identical to, e.g., CMP module 306, both of FIG. 3.

At process block 604, an ECD module may be provided in the stand-alone processing station. In some embodiments the ECD module may be similar or identical to, e.g., ECD module 304 of FIG. 3.

At process block 606, method 600 may include providing an input/output port in the stand-alone processing station. The input/output port may be configured to receive and return a semiconductor wafer to and from a wafer transport system of a semiconductor manufacturing system, wherein the wafer transport system is external to the stand-alone processing station. In some embodiments, method 600 may include providing two or more input/output ports. In some of those embodiments, one input/output port may serve as an input port for receiving wafers from other processing stations, while another input/output port may serve as an output port for sending wafers to other processing stations. In some embodiments, the input/output port may be either of input/output ports 319a or 319b of FIG. 3.

Method 600 may include at process block 608 providing a wafer handler in the stand-alone processing station. The wafer handler may be configured to transfer a wafer within the stand-alone processing station between the CMP module and the ECD module and/or between the input/output port and the CMP module. The wafer handler may be a single mechanism or may include two or more separate mechanisms wherein, e.g., one mechanism may be configured to transfer wafers between the CMP module and the ECD module and a second mechanism may be configured to transfer wafers between the input/output port and the CMP module. In some embodiments, the wafer handler may be configured to also transfer wafers between the input/output port and the ECD module. In some embodiments, the wafer handler may include either or both of wafer handlers 307 and 309 of FIG. 3.

At process block 610, a controller may be provided in the stand-alone processing station. The controller may be configured to automatically control processing and transfer of a semiconductor wafer within the stand-alone processing station, and in particular, in the CMP module and the ECD module. In some embodiments, the controller may be similar or identical to controller 311 of FIG. 3.

The above process blocks of methods 400 and 600 may be executed or performed in an order or sequence not limited to the order and sequence shown and described. For example, in connection with some embodiments of method 400, multiple wafers may be being processed at interconnect fabrication station 305 simultaneously. Accordingly, one or more of process blocks 402, 404, 406 and/or 408 may be performed, albeit not necessarily on the same wafer, before, after, or simultaneously with any other of process blocks 402, 404, 406, and/or 408. In connection with some embodiments of method 600, any of process blocks 602, 604, 606, 608, and/or 610 may be performed before, after, or simultaneously with any other of process blocks 602, 604, 606, 608, and/or 610.

Persons skilled in the art should readily appreciate that the invention described herein is susceptible of broad utility and application. Many embodiments and adaptations of the invention other than those described herein, as well as many variations, modifications, and equivalent arrangements, will be apparent from, or reasonably suggested by, the invention and the foregoing description thereof, without departing from the substance or scope of the invention. For example, although described in connection with forming interconnects in trenches, contacts, and/or vias on semiconductor wafers, one or more embodiments of the invention may be used with other types of interconnects, such as, e.g., TSVs (through silicon vias) and/or other types of substrates. Accordingly, while the invention has been described herein in detail in relation to specific embodiments, it should be understood that this disclosure is only illustrative and presents examples of the invention and is made merely for purposes of providing a full and enabling disclosure of the invention. This disclosure is not intended to limit the invention to the particular apparatus, devices, assemblies, systems or methods disclosed, but, to the contrary, the intention is to cover all modifications, equivalents, and alternatives falling within the scope of the invention.

What is claimed is:

1. An interconnect fabrication station comprising:
a chemical mechanical polishing (CMP) module;
an electro-chemical deposition (ECD) module; and
a controller electrically coupled to the CMP module and to the ECD module, the controller configured to:
cause the CMP module to remove a first top layer from a semiconductor wafer;
cause the ECD module to deposit a metal on the semiconductor wafer; and
cause the CMP module to remove excess deposited metal and a second top layer from the semiconductor wafer.

2. The interconnect fabrication station of claim 1 wherein the ECD module is configured to fill interconnect features on the semiconductor wafer with deposited metal and leave most of a top surface of the semiconductor wafer without deposited metal.

3. The interconnect fabrication station of claim 1 further comprising a first wafer handler coupled to the CMP module and to the ECD module, the first wafer handler configured to transfer a semiconductor wafer between the CMP module and the ECD module.

4. The interconnect fabrication station of claim 1 wherein the controller is configured to cause the semiconductor wafer to be transferred from the CMP module to the ECD module and from the ECD module to the CMP module.

5. The interconnect fabrication station of claim 1 further comprising an input/output port configured to receive and return a semiconductor wafer to and from a wafer transport system of a semiconductor manufacturing system, the wafer transport system external to the interconnect fabrication station.

6. The interconnect fabrication station of claim 5 wherein the controller is configured to cause a semiconductor wafer to be transferred from the input/output port to the CMP module and from the CMP module to the input/output port.

7. The interconnect fabrication station of claim 5 further comprising a second wafer handler coupled to the input/output port and to the CMP module, the second wafer handler configured to transfer a semiconductor wafer between the input/output port and the CMP module.

8. The interconnect fabrication station of claim 7 wherein the first wafer handler and the second wafer handler are each part of a same station wafer handling system.

9. The interconnect fabrication station of claim 1 wherein the first top layer comprises a barrier seed layer.

10. The interconnect fabrication station of claim 1, wherein the second top layer comprises a barrier layer.

11. The interconnect fabrication station of claim 1, wherein the metal comprises copper.

12. A method of forming an interconnect, the method comprising:
receiving a semiconductor wafer at an interconnect fabrication station configured to form one or more interconnects on a semiconductor wafer;
applying to the semiconductor wafer at the interconnect fabrication station a first selective chemical mechanical polishing process;
applying to the semiconductor wafer at the interconnect fabrication station a selective electro-chemical deposition process; and
applying to the semiconductor wafer at the interconnect fabrication station a second selective chemical mechanical polishing process.

13. The method of claim 12 wherein the applying to the semiconductor wafer at the interconnect fabrication station the first selective chemical mechanical polishing process comprises removing a barrier seed layer from a top surface of the semiconductor wafer.

14. The method of claim 12 wherein the applying to the semiconductor wafer at the interconnect fabrication station the second selective chemical mechanical polishing process comprises removing excess deposited metal and a barrier layer from a top surface of the semiconductor wafer.

15. The method of claim 12 wherein the received semiconductor wafer has interconnect features etched therein and a first layer deposited over a second layer.

16. The method of claim 15 wherein the interconnect features comprise at least one of a trench, via, or contact.

17. The method of claim 15, wherein the applying to the semiconductor wafer at the interconnect fabrication station the selective electro-chemical deposition process comprises depositing a metal in the interconnect features wherein no deposited metal remains on most of a top surface of the semiconductor wafer.

18. The method of claim 12 further comprising transferring the semiconductor wafer after the second selective chemical mechanical polishing process to an input/output port of the interconnect fabrication station for transport to another processing station of a semiconductor manufacturing system.

19. A method of forming an interconnect, comprising:
providing a chemical mechanical polishing (CMP) module in a stand-alone processing station;
providing an electro-chemical deposition (ECD) module in the stand-alone processing station;
providing an input/output port in the stand-alone processing station configured to receive and return a semiconductor wafer to and from a wafer transport system of a semiconductor manufacturing system, the wafer transport system external to the stand-alone processing station;
providing at least one wafer handler in the stand-alone processing station configured to transfer a wafer within the stand-alone processing station between the CMP module and the ECD module and between the input/output port and the CMP module; and
providing a controller in the stand-alone processing station configured to control processing of a semiconductor wafer in the CMP module and the ECD module and to control transfer of the semiconductor wafer within the stand-alone processing station.

20. The method of claim 19 wherein:
the CMP module is configured to remove a first layer from a top surface of a semiconductor wafer received from the input/output port and remove excess metal and a second layer from a top surface of a semiconductor wafer received from the ECD module; and
the ECD module is configured to deposit a metal in interconnect features of a semiconductor wafer received from the CMP module and leave no deposited metal on most of a top surface of the semiconductor wafer received from the CMP module.
